(19) United States
(12) Patent Application Publication
(10) Pub. No.: US 2016/0211332 A1
(43) Pub. Date: Jul. 21, 2016

(54) SILICON CARBIDE SEMICONDUCTOR DEVICE AND METHOD OF MANUFACTURING THE SAME

(71) Applicant: SUMITOMO ELECTRIC INDUSTRIES, LTD., Osaka (JP)

(72) Inventors: Toru Hiyoshi, Osaka-shi (JP); Takeyoshi Masuda, Osaka-shi (JP)

(21) Appl. No.: 14/911,678

(22) PCT Filed: Jul. 24, 2014
(86) PCT No.: PCT/JP2014/069515

§ 371 Date: Feb. 11, 2016

(30) Foreign Application Priority Data
Sep. 12, 2013 (JP) 2013-189581

(51) Int. Cl. H01L 29/16; H01L 29/06; H01L 29/732; H01L 29/10; H01L 29/417; H01L 29/66; H01L 21/3065; H01L 29/08

(52) U.S. Cl. CPC H01L 29/1608; H01L 21/3065; H01L 29/0692; H01L 29/0804; H01L 29/1004; H01L 29/41708; H01L 29/66068; H01L 29/7325

(57) ABSTRACT

A silicon carbide semiconductor device capable of achieving a high current gain with a simplified construction is provided. A silicon carbide layer includes a collector region, a base region, and an emitter region. The silicon carbide layer is provided with a trench having a sidewall surface reaching the base region from a first main surface through the emitter region. The sidewall surface includes a region macroscopically having an angle not smaller than 50° and not greater than 70° with respect to a {000-1} plane. A manufacturing method includes the step of forming a trench. The step of forming a trench includes the step of chemically treating the first main surface of the silicon carbide layer for forming the region.

### TECHNICAL FIELD

The present invention relates to a silicon carbide semiconductor device and a method of manufacturing the same, and in particular to a silicon carbide semiconductor device having a bipolar transistor and a method of manufacturing the same.

### BACKGROUND ART

Silicon carbide (SiC) has increasingly been adopted as a material forming a power semiconductor device (power semiconductor). Silicon carbide is a wide band gap semiconductor greater in band gap than silicon which has conventionally widely been used as a material forming a semiconductor device.

By adopting silicon carbide as a material forming a semiconductor device, a higher breakdown voltage and a lower on-resistance of a semiconductor device can be achieved. A semiconductor device in which silicon carbide has been adopted as a material is also advantageous in that lowering in characteristics during use in a high-temperature environment is less than in a semiconductor device in which silicon has been adopted as a material.

SiC power semiconductors are mainly categorized into junction devices and metal oxide semiconductor (MOS) devices. A representative example of the junction device is a bipolar transistor (also called a bipolar junction transistor (BJT)).

One challenge of the BJT formed of SiC is improvement in current gain. The current gain is defined as a ratio of a collector current to a base current. A low current gain may be caused by recombination of holes in a base region with electrons injected from an emitter region through interface states at a surface of the base region. As a density of electrons and holes is higher, a recombination current is higher. Alternatively, as the number of interface states is greater, a recombination current is higher.

For example, Japanese Patent Laying-Open No. 2006-351621 (PTD 1) discloses a bipolar silicon carbide semiconductor device aiming to improve a current gain. This semiconductor device has a recombination suppression semiconductor layer. The recombination suppression semiconductor layer is a layer containing a p-type impurity at a low concentration, and it is arranged around a surface of a semiconductor crystal between a base contact region and an emitter region. The recombination suppression semiconductor layer isolates a surface of a semiconductor where a large number of interface states are present from a portion where a hole current or an electron current mainly flows. Recombination between the holes and the electrons is thus suppressed.

### CITATION LIST

### Patent Document

PTD 1: Japanese Patent Laying-Open No. 2006-351621

### SUMMARY OF INVENTION

### Technical Problem

The invention disclosed in Japanese Patent Laying-Open No. 2006-351621 requires a special layer for suppressing recombination between electrons and holes. Therefore, a structure of a silicon carbide semiconductor device becomes complicated.

An object of the present invention is to provide a silicon carbide semiconductor device capable of achieving a high current gain with a simplified construction and a method of manufacturing the same.

### SOLUTION TO PROBLEM

A silicon carbide semiconductor device according to one aspect of the present invention includes a silicon carbide layer having hexagonal single-crystal structure. The silicon carbide layer includes a first main surface, a second main surface located opposite to the first main surface, a collector region having a first conductivity type and defining the second main surface, a base region having a second conductivity type different from the first conductivity type and arranged on a surface of the collector region opposite to the second main surface, and an emitter region having the first conductivity type, arranged on the base region as being spaced apart from the collector region, and defining the first main surface. The silicon carbide layer is provided with a trench having a sidewall surface reaching the base region from the first main surface through the emitter region. The sidewall surface includes a region macroscopically having an angle not smaller than 50° and not greater than 70° with respect to a {000-1 } plane.

A method of manufacturing a silicon carbide semiconductor device according to another aspect of the present invention includes the step of providing a silicon carbide layer having hexagonal single-crystal structure and having a first main surface and a second main surface located opposite to the first main surface. The step of preparing a silicon carbide layer includes the steps of forming a collector region having a first conductivity type and defining the second main surface, forming a base region having a second conductivity type different from the first conductivity type on a surface of the collector region opposite to the second main surface, and forming on the base region, an emitter region having the first conductivity type and defining the first main surface. The manufacturing method further includes the step of forming a trench having a sidewall surface reaching the base region through the emitter region. The step of forming a trench includes the step of chemically treating the first main surface of the silicon carbide layer for forming a region macroscopically having an angle not smaller than 50° and not greater than 70° with respect to a {000-1} plane.

### ADVANTAGEOUS EFFECTS OF INVENTION

According to the present invention, a silicon carbide semiconductor device capable of achieving a high current gain with a simplified construction can be realized.

### BRIEF DESCRIPTION OF DRAWINGS

FIG. 1 is a plan view showing a schematic construction of a silicon carbide semiconductor device according to a first embodiment of the present invention.

FIG. 2 is a cross-sectional view along the line II-II in FIG. 1.

FIG. 3 is a diagram for illustrating a direction a₁₁ and a direction a₂₁ shown in FIGS. 1 and 2.

FIG. 4 is a partial cross-sectional view schematically showing a first step in a method of manufacturing a silicon carbide semiconductor device 1 according to the first embodiment.

FIG. 5 is a partial cross-sectional view schematically showing a second step in the method of manufacturing silicon carbide semiconductor device 1 according to the first embodiment.

FIG. 6 is a partial cross-sectional view schematically showing a third step in the method of manufacturing silicon carbide semiconductor device 1 according to the first embodiment.

FIG. 7 is a partial cross-sectional view schematically showing a fourth step in the method of manufacturing silicon carbide semiconductor device 1 according to the first embodiment.

FIG. 8 is a partial cross-sectional view schematically showing a fifth step in the method of manufacturing silicon carbide semiconductor device 1 according to the first embodiment.

FIG. 9 is a partial cross-sectional view schematically showing a sixth step in the method of manufacturing silicon carbide semiconductor device 1 according to the first embodiment.

FIG. 10 is a partial cross-sectional view schematically showing a seventh step in the method of manufacturing silicon carbide semiconductor device 1 according to the first embodiment.

FIG. 11 is a partial cross-sectional view schematically showing an eighth step in the method of manufacturing silicon carbide semiconductor device 1 according to the first embodiment.

FIG. 12 is a diagram for illustrating a basic operation of an npn transistor.

FIG. 13 is a diagram showing a construction of a comparative example of an silicon carbide semiconductor device according to an embodiment of the present invention.

FIG. 14 is a cross-sectional view showing another construction of silicon carbide semiconductor device 1 according to the first embodiment.

FIG. 15 is a plan view showing a schematic construction of a silicon carbide semiconductor device according to a second embodiment of the present invention.

FIG. 16 is a cross-sectional view along the line XVI-XVI in FIG. 15.

FIG. 17 is a partial cross-sectional view schematically showing a first treatment performed in a fourth step (a step of forming a trench) in a method of manufacturing a silicon carbide semiconductor device 1A according to the second embodiment.

FIG. 18 is a cross-sectional view schematically showing a second treatment performed in the fourth step (the step of forming a trench) in the method of manufacturing silicon carbide semiconductor device 1A according to the second embodiment.

FIG. 19 is a cross-sectional view schematically showing fifth and sixth steps in the method of manufacturing silicon carbide semiconductor device 1A according to the second embodiment.

FIG. 20 is a plan view showing a schematic construction of a silicon carbide semiconductor device according to a third embodiment of the present invention.

FIG. 21 is a cross-sectional view along the line XXI-XXI in FIG. 20.

FIG. 22 is a partial cross-sectional view schematically showing a first treatment performed in a fourth step (a step of forming a trench) in a method of manufacturing a silicon carbide semiconductor device 1B according to the third embodiment.

FIG. 23 is a cross-sectional view schematically showing a second treatment performed in the fourth step (the step of forming a trench) in the method of manufacturing silicon carbide semiconductor device 1B according to the third embodiment.

FIG. 24 is a cross-sectional view schematically showing fifth and six steps in the method of manufacturing silicon carbide semiconductor device 1B according to the third embodiment.

FIG. 25 is a diagram showing a depletion layer extending from a junction surface of a pn junction.

FIG. 26 is another diagram showing a depletion layer extending from a junction surface of a pn junction.

### DESCRIPTION OF EMBODIMENTS

### [Description of Embodiments of the Invention of the Present Application]

Embodiments of the present invention will initially be listed and described. Regarding crystallographic denotation herein, an individual orientation, a group orientation, an individual plane, and a group plane are shown in [ ], < >, ( ) and { }, respectively. Moreover, a crystallographically negative index is normally expressed by a number with a bar “-” thereabove, however, a negative sign herein precedes a number. In expressing an angle, a system in which a total azimuth angle is defined as 360 degrees is employed.

(1) A silicon carbide semiconductor device (1, 1A, 1B) according to an embodiment of the present invention includes a silicon carbide layer (10) having hexagonal single-crystal structure. The silicon carbide layer (10) includes a first main surface (10a), a second main surface (10b) located opposite to the first main surface (10a), a collector region (11, 12) having a first conductivity type and defining a second main surface (10b), a base region (13) having a second conductivity type different from the first conductivity type and arranged on a surface of the collector region opposite to the second main surface (10b), and an emitter region (14) having the first conductivity type, arranged on the base region (13) as being spaced apart from the collector region (11, 12), and defining the first main surface (10a). The silicon carbide layer (10) is provided with a trench (TR) having a sidewall surface reaching the base region (13) from the first main surface (10a) through the emitter region (14). The sidewall surface includes a first region (SW1) macroscopically having an angle not smaller than 50° and not greater than 70° with respect to a {1000-1} plane.

According to this construction, the silicon carbide layer has the sidewall surface reaching the base region from the first main surface of the silicon carbide layer through the emitter region. The sidewall surface includes the first region macroscopically having an angle not smaller than 50° and not greater than 70° with respect to the {1000-1} plane. This first region is a crystal plane having a low interface state density (which may also hereinafter be called a “special surface” herein). “Macroscopic” means ignoring a microstructure having a dimension as small as interatomic spacing. Such a macroscopic off angle can be measured, for example, with a general method using X-ray diffraction.

As holes and electrons are recombined, a base current is produced. As the base current is higher, a current gain of the silicon carbide semiconductor device (bipolar transistor) is lowered. One of factors for recombination between holes and electrons is interface states of the silicon carbide layer. Since the first region of the sidewall surface is a plane selected as a plane having a low interface state density, a recombination current can be lowered. A silicon carbide semiconductor device having a high current gain can thus be realized.

(2) Preferably, the first region (SW1) includes a plane having a plane orientation {0-33-8}.

According to this construction, a recombination current can be lowered. A silicon carbide semiconductor device having a high current gain can thus be realized.

(3) Preferably, the sidewall surface includes two surfaces (SWa, SWb) opposed to each other and coming closer to each other from the first main surface (10a) of the silicon carbide layer (10) toward the second main surface (10b).

According to this construction, the first region can be exposed. Therefore, a silicon carbide semiconductor device having a high current gain can be realized.

The trench may have a bottom surface and the two surfaces may continue to the bottom surface. Alternatively, the two surfaces of the trench may continue to each other. In the latter case, the trench can have a smaller width at the first main surface. A pitch between bipolar transistor cells can thus be smaller.

(4) Preferably, the first region (SW1) is arranged to lie across the emitter region (14) and the base region (13). The sidewall surface further includes a second region (SW2) having a depth from the first main surface (10a) of the silicon carbide layer (10) to a position shallower than a junction surface between the emitter region (14) and the base region (13) and continuing to the first region (SW1). An angle (θ2) formed by the second region (SW2) with respect to the first main surface (10a) is greater than an angle (θ1) formed by the first region (SW1) with respect to the first main surface (10a).

According to this construction, a current gain of the silicon carbide semiconductor device can further be higher. A plane having a low interface state density has been selected as the first region. The first region lies across both of the emitter region and the base region. Therefore, a probability of occurrence of recombination between holes and electrons can be lower. A current gain of the silicon carbide semiconductor device can thus be higher.

(5) Preferably, the first region (SW1) is arranged in the base region (13). The sidewall surface further includes a second region (SW2) continuing from the first main surface (10a) of the silicon carbide layer (10) through the emitter region (14) to the first region (SW1). An angle (θ2) formed by the second region (SW2) with respect to the first main surface (10a) is greater than an angle (θ1) formed by the first region (SW1) with respect to the first main surface (10a).

According to this construction, a breakdown voltage of the silicon carbide semiconductor device can be ensured. A junction surface between the emitter region and the base region intersects with the second region. As an angle formed by the second region with respect to the first main surface is smaller, a depletion layer is less likely to extend at an end portion of the junction surface close to the second region. An angle formed by the second region with respect to the first main surface of the silicon carbide layer is greater than an angle formed by the first region with respect to the first main surface. Therefore, a depletion layer readily extends at the end portion of the junction surface close to the second region. As the depletion layer extends, a breakdown voltage of the silicon carbide semiconductor device can be ensured.

(6) Preferably, an n-type is defined as the first conductivity type and a p-type is defined as the second conductivity type.

According to this construction, an npn bipolar transistor can be implemented. Ease in manufacturing of a silicon carbide semiconductor device can further be improved.

(7) A method of manufacturing a silicon carbide semiconductor device according to an embodiment of the present invention includes the step of providing a silicon carbide layer (10) having hexagonal single-crystal structure and having a first main surface (10a) and a second main surface (10b) located opposite to the first main surface (10a). The step of preparing a silicon carbide layer (10) includes the steps of forming a collector region (11, 12) having a first conductivity type and defining the second main surface (10b), forming a base region (13) having a second conductivity type different from the first conductivity type on a surface of the collector region (11, 12) opposite to the second main surface (10b), and forming on the base region (13), an emitter region (14) having the first conductivity type and defining the first main surface (10a). The manufacturing method further includes the step of forming a trench (TR) having a sidewall surface reaching the base region (13) through the emitter region (14). The step of forming a trench (TR) includes the step of chemically treating the first main surface (10a) of the silicon carbide layer (10) for forming a first region (SW1) macroscopically having an angle not smaller than 50° and not greater than 70° with respect to a {1000-1} plane.

According to this construction, a silicon carbide semiconductor device having a high current gain can be manufactured.

(8) Preferably, the first region (SW1) includes a plane having a plane orientation {0-33-8}.

According to this construction, a silicon carbide semiconductor device having a high current gain can be manufactured.

(9) Preferably, the step of chemically treating the first main surface (10a) includes the step of chemically etching the first main surface (10a) of the silicon carbide layer (10).

According to this construction, the first region can more reliably be exposed.

(10) Preferably, the step of chemically etching the first main surface (10a) includes the step of thermally etching the first main surface (10a).

According to this construction, the first region can more reliably be exposed.

(11) Preferably, the step of thermally etching the first main surface (10a) includes the step of heating the silicon carbide layer (10) in an atmosphere containing one or more types of halogen atoms.

According to this construction, the first region can more reliably be exposed.

(12) Preferably, the one or more types of halogen atoms include at least any of chlorine atoms and fluorine atoms.

According to this construction, the first region can more reliably be exposed.

(13) Preferably, the step of forming a trench includes the step of etching the first main surface (10a) through reactive ion etching prior to the step of chemically treating the first main surface (10a) of the silicon carbide layer (10).

According to this construction, a region in the first main surface which corresponds to the trench is etched in advance through reactive ion etching. Then, the first main surface is chemically treated. Here, etching of the silicon carbide layer can smoothly proceed. Therefore, the first region can more reliably be exposed.

(14) Preferably, in the step of etching the first main surface through reactive ion etching, a second region (SW2) of the sidewall surface is formed by etching the emitter region (14) from the first main surface (10a) of the silicon carbide layer (10) to a position shallower than a junction surface between the emitter region (14) and the base region (13).

According to this construction, the first region lying across both of the emitter region and the base region can be formed. Therefore, a probability of occurrence of recombination between holes and electrons can be lowered. A current gain of the silicon carbide semiconductor device can thus be higher.

(15) Preferably, in the step of etching the first main surface through reactive ion etching, a second region (SW2) of the sidewall surface reaching the base region (13) from the first main surface (10a) of the silicon carbide layer (10) through the emitter region (14) is formed.

According to this construction, an angle formed by the second region with respect to the first main surface can be greater than an angle formed by the first region with respect to the first main surface. In addition, a junction surface between the emitter region and the base region intersects with the second region. Thus, a depletion layer readily extends at an end portion of the junction surface close to the second region. As the depletion layer extends, a breakdown voltage of the silicon carbide semiconductor device can be ensured.

(16) Preferably, the step of forming a base region (13) includes the step of forming a layer having the second conductivity type on the collector region (11, 12) through epitaxial growth.

According to this construction, a density of crystal defects can be lower than in a case that the base region is formed through ion implantation into the collector region. Thus, a current gain of the silicon carbide semiconductor device can be enhanced.

(17) Preferably, the step of forming an emitter region (14) includes the step of forming a layer having the first conductivity type on the base region (13) through epitaxial growth.

According to this construction, a density of crystal defects can be lower than in a case that the emitter region is formed through ion implantation into the base region. Thus, a current gain of the silicon carbide semiconductor device can be enhanced.

(18) Preferably, an n-type is defined as the first conductivity type and a p-type is defined as the second conductivity type.

According to this construction, an npn bipolar transistor can be implemented. Ease in manufacturing of a silicon carbide semiconductor device can further be improved.

### Details of Embodiments of the Invention of the Present Application

An embodiment of the present invention will be described hereinafter with reference to the drawings. In the drawings below, the same or corresponding elements have the same reference characters allotted and description thereof will not be repeated.

### First Embodiment

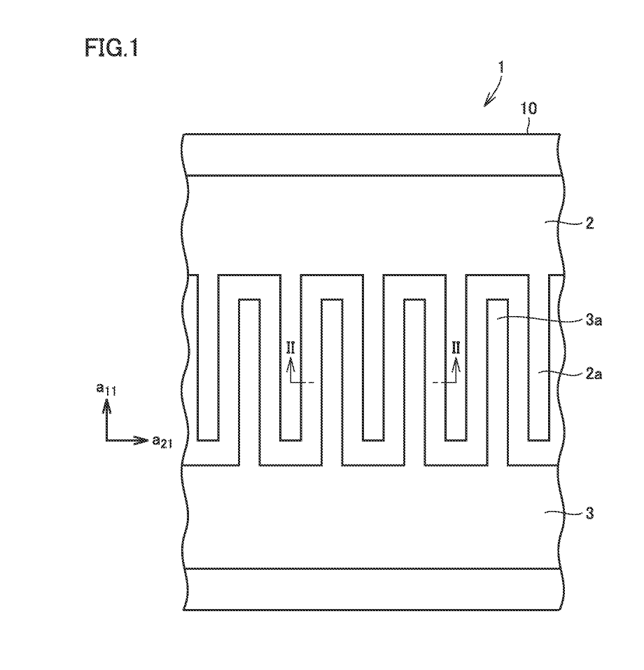

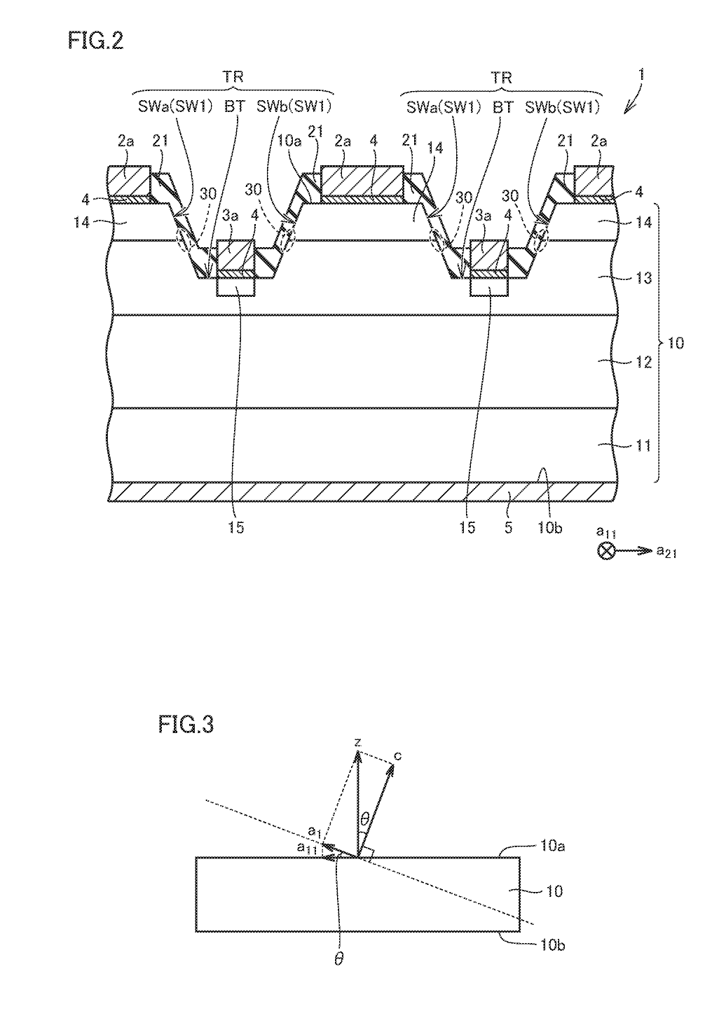

FIG. 1 is a plan view showing a schematic construction of a silicon carbide semiconductor device according to a first embodiment of the present invention. FIG. 2 is a cross-sectional view along the line II-II in FIG. 1.

Referring to FIGS. 1 and 2, a silicon carbide semiconductor device 1 according to the first embodiment is a bipolar transistor. More specifically, silicon carbide semiconductor device 1 according to the first embodiment is an npn bipolar transistor.

Silicon carbide semiconductor device 1 includes a silicon carbide layer 10, an insulating film 21, an emitter electrode 2a, a base electrode 3a, an ohmic electrode 4, and a collector electrode 5. As shown in FIG. 1, in a plan view, emitter electrode 2a and base electrode 3a extend along a direction shown with a₁₁ and alternately aligned along a direction shown with a₂₁. Direction all and direction a₂₁ are directions orthogonal to each other. Direction all and direction a₂₁ will be described in detail later.

Silicon carbide layer 10 has a first main surface 10a and a second main surface 10b located opposite to first main surface 10a. In one embodiment, silicon carbide layer 10 has hexagonal single-crystal structure. More preferably, silicon carbide layer 10 has hexagonal single-crystal structure having a polytype 4H.

Silicon carbide layer 10 includes an n⁺ substrate 11, an n-type layer 12, a p-type layer 13, and an n⁺ type layer 14.

N⁺ substrate 11 and n-type layer 12 implement a collector region of the bipolar transistor. One surface of n⁺ substrate 11 defines second main surface 10b of silicon carbide layer 10.

N⁺ substrate 11 is composed, for example, of hexagonal silicon carbide having a polytype 4H. N⁺ substrate 11 contains an impurity (donor) at a high concentration. A concentration of an impurity contained in n⁺ substrate 11 is, for example, around 1.0×10¹⁸ cm⁻³. A type of an impurity is, for example, nitrogen (N).

N-type layer 12 is arranged on the other surface (a surface opposite to second main surface 10b) of n⁺ substrate 11. N-type layer 12 is, for example, a layer formed through epitaxial growth. N-type layer 12 is composed, for example, of hexagonal silicon carbide having a polytype 4H. N-type layer 12 has a thickness, for example, not smaller than approximately 5 μm and not greater than approximately 200 μm. A concentration of an impurity contained in n-type layer 12 is, for example, not lower than approximately 1×10¹⁴ cm⁻³ and not higher than approximately 3×10¹⁶ cm⁻³. An impurity contained in n-type layer 12 is, for example, nitrogen (N).

P-type layer 13 implements a base region of the bipolar transistor. P-type layer 13 is arranged on a surface of the collector region (n-type layer 12) opposite to second main surface 10b of silicon carbide layer 10.

In this embodiment, p-type layer 13 is a layer formed on the collector region (n-type layer 12) through epitaxial growth. P-type layer 13 is composed, for example, of hexagonal silicon carbide having a polytype 4H. P-type layer 13 has a thickness, for example, not smaller than approximately 0.1 μm and not greater than approximately 0.8 μm. A concentration of an impurity contained in p-type layer 13 is, for example, not lower than approximately 7×10¹⁶ cm⁻³ and not higher than approximately 5×10¹⁸ cm⁻³. An impurity contained in p-type layer 13 is, for example, aluminum (Al) or boron (B).

N⁺ type layer 14 implements an emitter region of the bipolar transistor. N⁺ layer 14 is arranged on the base region (p-type layer 13) as being spaced apart from the collector region (n⁺ substrate 11 and n-type layer 12). A surface of n⁺ type layer 14 defines first main surface 10a of silicon carbide layer 10.

In this embodiment, n⁺ type layer 14 is a layer formed through epitaxial growth. N⁺ type layer 14 is composed, for example, of hexagonal silicon carbide having a polytype 4H. N⁺ type layer 14 has a thickness, for example, not smaller than approximately 0.2 μm and not greater than approximately 1 μm. A concentration of an impurity contained in n⁺ type layer 14 is, for example, not lower than approximately 1×10¹⁹ cm⁻³ and not higher than approximately 1×10²⁰ cm⁻³. An impurity contained in n⁺ type layer 14 is, for example, phosphorus (P).

A trench TR is arranged in silicon carbide layer 10. Trench TR has a sidewall surface SWa, a sidewall surface SWb, and a bottom surface BT.

Sidewall surfaces SWa and SWb are opposed to each other. Each of sidewall surfaces SWa and SWb reaches p-type layer 13 (base region) from first main surface 10a of silicon carbide layer 10 through n⁺ type layer 14 (emitter region).

Sidewall surfaces SWa and SWb are surfaces inclined with respect to first main surface 10a such that they come closer to each other from first main surface 10a of silicon carbide layer 10 toward second main surface 10b. Namely, trench TR has a width along direction a₂₁ decreasing from first main surface 10a of silicon carbide layer 10 toward second main surface 10b.

Bottom surface BT is a surface continuing to sidewall surfaces SWa and SWb. Bottom surface BT is located in p-type layer 13. A distance from first main surface 10a to bottom surface BT (a depth of bottom surface BT of trench TR from first main surface 10a) is, for example, not smaller than approximately 0.3 μm and not greater than approximately 1.5 μm.

In this embodiment, sidewall surfaces SWa and SWb include a first region SW1. First region SW1 includes a prescribed crystal plane (also referred to as a special surface). Specifically, sidewall surfaces SWa and SWb include a region (first region) macroscopically having an angle not smaller than 50° and not greater than 70° with respect to a {000-1} plane. More preferably, this region may include a plane having a plane orientation {0-33-8}. In this embodiment, each of sidewall surfaces SWa and SWb in its entirely implements the first region. Each of sidewall surfaces SWa and SWb should only include first region SW1. As sidewall surfaces SWa and SWb including the special surface are exposed, a current gain of the silicon carbide semiconductor device can be higher as will be described later.

P⁺ type region 15 is formed in bottom surface BT of trench TR in p-type layer 13. A depth of p⁺ type region 15 from the surface of p-type layer 13 is smaller than a thickness of p-type layer 13 in that portion. A depth of p⁺ type region 15 from the surface of p-type layer 13 is, for example, not smaller than approximately 0.1 μm and not greater than approximately 1 μm. A concentration of an impurity contained in p⁺ type region 15 is higher than a concentration of an impurity contained in p-type layer 13. For example, a concentration of an impurity in p⁺ type region 15 is not lower than approximately 1×10¹⁹ cm⁻³ and not higher than approximately 1×10²⁰ cm⁻³. An impurity contained in p⁺ type region 15 is, for example, aluminum (Al) or boron (B).

Insulating film 21 covers first main surface 10a of silicon carbide layer 10 and an inner peripheral surface (sidewall surfaces SWa and SWb and bottom surface BT) of trench TR. In one embodiment, insulating film 21 is formed from an oxide film, and more specifically from a film composed of silicon dioxide (SiO₂). A contact hole for exposing n⁺ type layer 14 and p⁺ type region 15 is formed in insulating film 21.

Ohmic electrode 4 is arranged in the contact hole formed in insulating film 21 and establishes ohmic contact with n⁺ type layer 14 or p⁺ type region 15. Ohmic electrode 4 is preferably composed of a material having nickel and silicon. Ohmic electrode 4 may be composed of a material having titanium, aluminum, and silicon.

Collector electrode 5 is formed as being in contact with second main surface 10b of silicon carbide layer 10. Collector electrode 5 may be composed of a material which can establish ohmic contact with n⁺ substrate 11. Collector electrode 5 may be composed, for example, similarly to ohmic electrode 4, or may be composed of another material which can establish ohmic contact with n⁺ substrate 11, such as nickel.

Base electrode 3a is in contact with ohmic electrode 4 arranged on p⁺ type region 15. Base electrode 3a is thus electrically connected to p⁺ type region 15 and p-type layer 13.

Emitter electrode 2a is in contact with ohmic electrode 4 arranged on n⁺ type layer 14. Emitter electrode 2a is thus electrically connected to n⁺ type layer 14.

FIG. 3 is a diagram for illustrating direction a₁₁ and direction a₂₁ shown in FIGS. 1 and 2. Referring to FIG. 3, direction all indicates a <11-20> direction and direction a₂₁ indicates a <1-100> direction. Main surface 10a of silicon carbide layer 10 is, for example, a surface angled off (inclined) in a direction au by an off angle θ from a {0001} plane (shown with a dashed line).

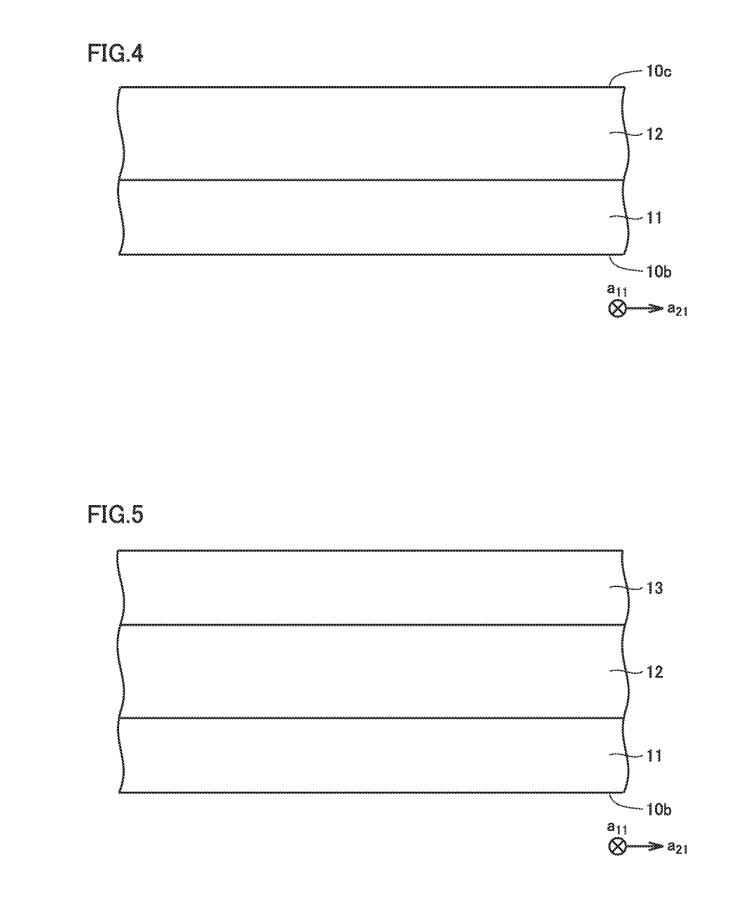

Off angle θ is preferably not greater than 8°, and it is, for example, 4° or 8°. Specifically, a main surface 10c of n-type layer 12 (FIG. 4) is a surface angled off from the {0001} plane such that a normal vector z of main surface 10c has at least one component of <11-20> and <1-100>. Preferably, main surface 10c is a surface angled off from the {0001} plane such that normal vector z of main surface 10c has a component of <11-20>. In FIG. 3, a direction c indicates a [0001] direction (that is, a c axis of hexagonal silicon carbide) and direction al indicates, for example, a <11-20> direction. An off direction refers to a direction in which normal vector z of main surface 10c is inclined from the [0001] direction. In FIG. 3, the off direction is defined as the ai direction, that is, the <11-20> direction). In FIG. 4, main surface 10c is such a surface that a (0001) plane is angled off in the a₁ direction. An in-plane off direction refers to a direction defined by projecting the off direction (a₁ direction) on main surface 10c. In this embodiment, the in-plane off direction is defined as the a₁₁ direction.

FIG. 4 is a partial cross-sectional view schematically showing a first step in a method of manufacturing silicon carbide semiconductor device 1 according to the first embodiment. The first step corresponds to the step of forming a collector region having the n-type and defining second main surface 10b. Referring to FIG. 4, initially, single-crystal n⁺ substrate 11 is provided. Then, n-type layer 12 is formed on single-crystal n⁺ substrate 11 through epitaxial growth of silicon carbide.

Epitaxial growth can be carried out with chemical vapor deposition (CVD). Here, a hydrogen gas can be used as a carrier gas. A gas mixture, for example, of silane (SiH₄) and propane (C₃H₈) can be used as a source gas. Here, for example, nitrogen (N) or phosphorus (P) is preferably introduced as an impurity for providing the n-type to silicon carbide.

FIG. 5 is a partial cross-sectional view schematically showing a second step in the method of manufacturing silicon carbide semiconductor device 1 according to the first embodiment. The second step corresponds to the step of forming a base region having the p-type different from the n-type on the surface of the collector region opposite to second main surface 10b. Referring to FIG. 5, p-type layer 13 is formed on n-type layer 12 through epitaxial growth of silicon carbide.

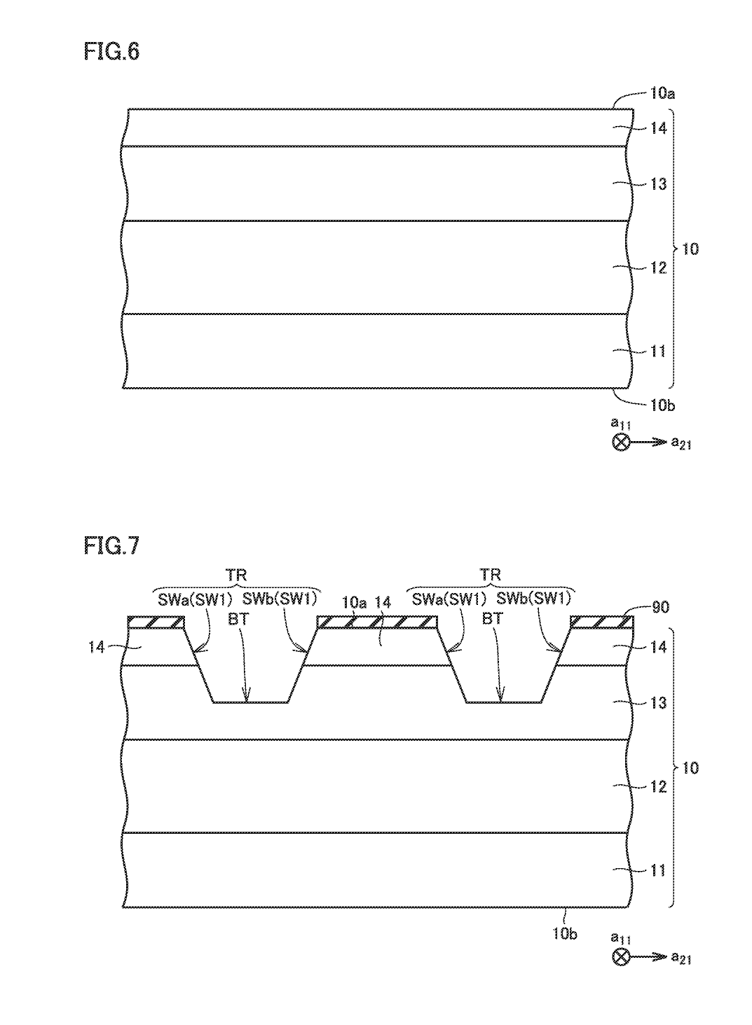

FIG. 6 is a partial cross-sectional view schematically showing a third step in the method of manufacturing silicon carbide semiconductor device 1 according to the first embodiment. The third step corresponds to the step of forming on the base region, an emitter region having the n-type and defining first main surface 10a. Referring to FIG. 6, n⁺ type layer 14 is formed on p-type layer 13 through epitaxial growth of silicon carbide.

In another method, p-type layer 13 may be formed by implanting p-type impurity ions into n-type layer 12. Furthermore, n⁺ type layer 14 may be formed by implanting n-type impurity ions into p-type layer 13. Alternatively, n⁺ type layer 14 may be formed by forming p-type layer 13 on n-type layer 12 and then implanting n-type impurity ions into p-type layer 13. By forming p-type layer 13 and n⁺ type layer 14 through epitaxial growth, however, a density of crystal defects included in p-type layer 13 and n⁺ type layer 14 can be lowered.

FIG. 7 is a partial cross-sectional view schematically showing a fourth step in the method of manufacturing silicon carbide semiconductor device 1 according to the first embodiment. The fourth step corresponds to the step of forming trench TR having sidewall surfaces SWa and SWb reaching the base region through the emitter region. Referring to FIG. 7, initially, a mask layer 90 having an opening in a region where trench TR is to be formed in first main surface 10a of silicon carbide layer 10 and composed, for example, of silicon dioxide (SiO₂) is formed, for example, through plasma-chemical vapor deposition (P-CVD). Then, first main surface 10a of silicon carbide layer 10 is chemically treated. In one embodiment, one main surface 10a of silicon carbide layer 10 is chemically etched. More preferably, first main surface 10a of silicon carbide layer 10 is thermally etched.

Thermal etching can be performed, for example, through heating in an atmosphere containing a reactive gas having one or more types of halogen atoms. One or more types of halogen atoms include at least any of chlorine (Cl) atoms and fluorine (F) atoms. This atmosphere is, for example, of Cl₂, BCl₃, SF₆, or CF₄. Thermal etching is performed in such a manner that, for example, a gas mixture of a chlorine gas and an oxygen gas is used as a reaction gas and a temperature for heat treatment, for example, not lower than 700° C. and not higher than 1000° C. is set.

The reaction gas may contain a carrier gas in addition to the chlorine gas and the oxygen gas described above. For example, a nitrogen (N₂) gas, an argon gas, a helium gas, or the like can be employed as a carrier gas. Then, in a case where a temperature for heat treatment not lower than 700° C. and not higher than 1000° C. is set as described above, a rate of etching of silicon carbide attains, for example, to approximately 70 μm/hour.

The step of thermal etching is the step of chemically treating the first main surface of the silicon carbide layer for forming the first region macroscopically having an angle not smaller than 50° and not greater than 70° with respect to the {000-1} plane. More preferably, the step of thermal etching is the step of forming the first region including a plane having a plane orientation {0-33-8}. Through such a treatment, a special surface can be exposed. As thermal etching is completed, mask layer 90 is removed.

FIG. 8 is a partial cross-sectional view schematically showing a fifth step in the method of manufacturing silicon carbide semiconductor device 1 according to the first embodiment. Referring to FIG. 8, p⁺ type region 15 is formed in p-type layer 13.

For example, a thermal oxide film is formed on the surface of p-type layer 13. Then, a photoresist film having an opening corresponding to p⁺ type region 15 formed is formed on the thermal oxide film through lithography. Through etching of the thermal oxide film and removal of the photoresist film, an opening pattern is transferred to the thermal oxide film. Ion implantation of a p-type impurity and activation heat treatment are carried out. P⁺ type region 15 is thus formed.

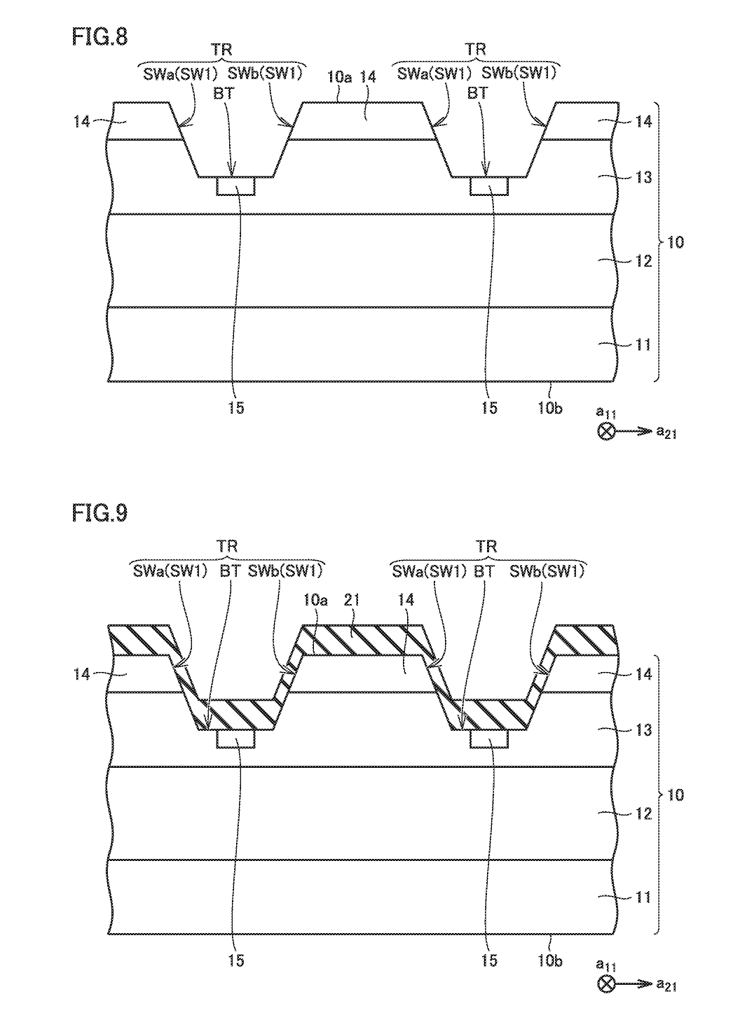

FIG. 9 is a partial cross-sectional view schematically showing a sixth step in the method of manufacturing silicon carbide semiconductor device 1 according to the first embodiment. Referring to FIG. 9, insulating film 21 covering first main surface 10a, sidewall surfaces SWa and SWb, and bottom surface BT is formed. In this embodiment, insulating film 21 is formed, for example, by oxidizing the surface of silicon carbide layer 10. Specifically, insulating film 21 is composed, for example, of silicon dioxide (SiO₂).

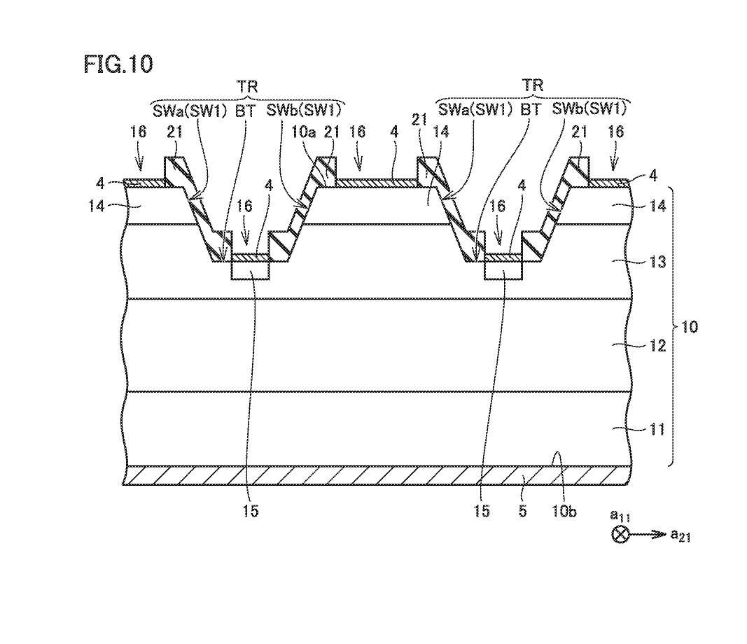

FIG. 10 is a partial cross-sectional view schematically showing a seventh step in the method of manufacturing silicon carbide semiconductor device 1 according to the first embodiment. Referring to FIG. 10, a contact hole 16 for exposing n⁺ type layer 14 and p⁺ type region 15 is formed in insulating film 21. Then, ohmic electrode 4 is arranged in contact hole 16 formed in insulating film 21.

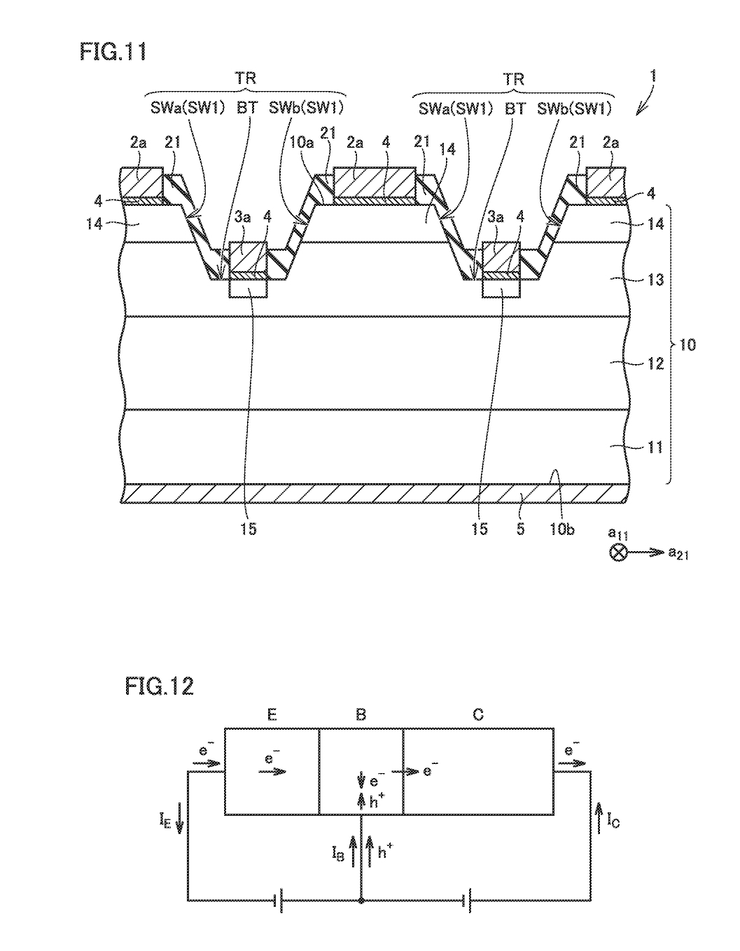

FIG. 11 is a partial cross-sectional view schematically showing an eighth step in the method of manufacturing silicon carbide semiconductor device 1 according to the first embodiment. Referring to FIG. 11, an electrode material such as aluminum is deposited on a side of first main surface 10a of silicon carbide layer 10 through sputtering. A conductive film is thus formed. Then, a photoresist film is formed in a region corresponding to emitter electrode 2a and base electrode 3a through a lithography process. The electrode material is removed to leave a pattern for emitter electrode 2a and base electrode 3a through etching. Thereafter, the photoresist film is removed. Emitter electrode 2a and base electrode 3a are thus formed.

Collector electrode 5 may be formed simultaneously with emitter electrode 2a and base electrode 3a or in a different step.

FIG. 12 is a diagram for illustrating a basic operation of an npn transistor. Referring to FIG. 12, a forward bias voltage is applied across the emitter (E) and the base (B) and a reverse bias voltage is applied across the collector (C) and the base.

Electrons (e⁻) are injected into the emitter (E). An emitter current IE is thus produced. Holes (h⁺) are injected into the base (B). In the base, as the holes and the electrons are combined with each other, a base current I_{B} is produced. By decreasing a thickness of a base layer, most of the electrons which have flowed into the base (B) reach a portion of junction between the base and the collector. Then, owing to a difference in potential between the base and the collector, the electrons diffuse into the collector. A collector current I_{C} is thus produced.

A current gain (h_{PE}) of a bipolar transistor is defined as a ratio of collector current I_{C} to base current I_{B}. As described above, collector current I_{C} is produced as electrons injected into the emitter reach the collector. Therefore, in order to enhance the current gain, a probability of combination of holes and electrons in the base should be minimized. Namely, in order to enhance the current gain, base current I_{B} should be lowered.

Three techniques below can be exemplified as effective techniques for lowering a base current. A first technique is to lower a concentration of doping the base. A second technique is to decrease a width of the base. A third technique is to lower a density of crystal defects or an interface state density in the base. A concentration of doping the emitter may be lowered in order to lower a base current. In order to enhance the current gain, however, the number of electrons which will reach the collector from the emitter through the base is preferably increased. Therefore, a concentration of doping the emitter is desirably high.

In this embodiment, in order to lower a density of crystal defects in the base region, the base region is formed through epitaxial growth. A probability of recombination between electrons and holes in the base region can thus be lowered. Furthermore, in order to lower a density of crystal defects in the emitter region, the emitter region is formed through epitaxial growth. By lowering the density of crystal defects in the emitter region, a probability of electrons being captured (trapped) in the emitter region can be lowered. Therefore, the current gain can be enhanced.

In forming the emitter region on the base region through epitaxial growth, the base region is covered with the emitter region. In order to secure electrical connection between the base region (p-type layer 13) and base electrode 3a, trench TR is formed as extending from first main surface 10a of silicon carbide layer 10. Trench TR can expose the base region on a side of first main surface 10a. Therefore, electrical connection between the base region and the base electrode can be secured.

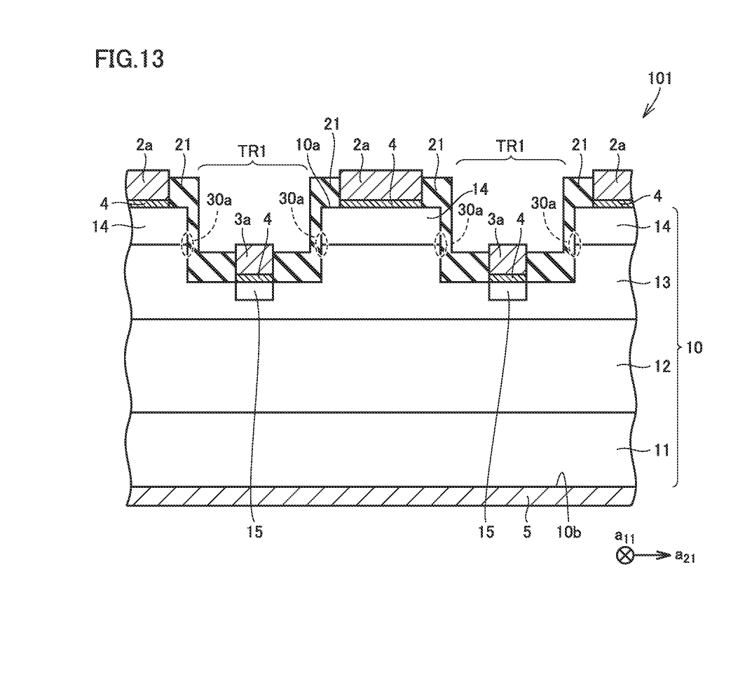

FIG. 13 is a diagram showing a construction of a silicon carbide semiconductor device in which an inner peripheral surface of a trench does not include a special surface. Referring to FIG. 13, a trench TR1 is arranged in a silicon carbide semiconductor device 101. Trench TR1 exposes p-type layer 13 (base region) as it extends from first main surface 10a through n⁺ type layer 14 (emitter region), for example, through reactive ion etching (RIE). A surface of trench TR1 is covered with insulating film 21.

When a sidewall surface (that is, a surface intersecting with a main surface) of a trench is covered with an insulating film, in general, the insulating film is formed by oxidizing an underlying semiconductor layer, because it is difficult to cover a sidewall surface of the trench with an oxide film having a uniform and sufficient thickness through vapor deposition with CVD.

For the reason above, an oxide film (SiO₂) is applied as insulating film 21. Namely, the sidewall surface of the trench corresponds to an interface between the oxide film and the silicon carbide layer. Electrons and holes are recombined with each other owing to interface states present at this interface. A region 30a is an interface at a position of j unction between n⁺ type layer 14 and p-type layer 13. For example, holes and electrons are likely to combine with each other in region 30a.

In particular, silicon carbide tends to be higher in interface state density than silicon. Therefore, a probability of recombination between holes and electrons is high at the interface of p-type layer 13. That is, a base current increases. For such a reason, a current gain is required to improve.

Referring back to FIG. 2, in this embodiment, sidewall surfaces SWa and SWb of trench TR include a special surface. The special surface is a plane selected in advance as a plane low in interface state density. Therefore, a probability of combination between holes and electrons in region 30 can be lowered. Since the base current can thus be lowered, silicon carbide semiconductor device 1 can obtain a high current gain.

Sidewall surfaces SWa and SWb of trench TR are surfaces inclined with respect to first main surface 10a of silicon carbide layer 10. Furthermore, trench TR has a width along direction a₂₁ increasing toward first main surface 10a. On the other hand, in silicon carbide semiconductor device 101 shown in FIG. 13, the sidewall surface of trench TR1 is substantially perpendicular to first main surface 10a of silicon carbide layer 10. Therefore, an interval between transistor cells along direction a₂₁ in FIG. 2 may be greater than in the construction shown in FIG. 13. Namely, a density of cells may be lower. Based on comparison between transistor cells, however, silicon carbide semiconductor device 1 can be higher in current gain than silicon carbide semiconductor device 101. Therefore, silicon carbide semiconductor device 1 as a whole can be higher in current gain than silicon carbide semiconductor device 101 as a whole.

A cross-sectional shape of trench TR is not limited to that as shown in FIG. 2. Sidewall surfaces SWa and SWb should only include a special surface.

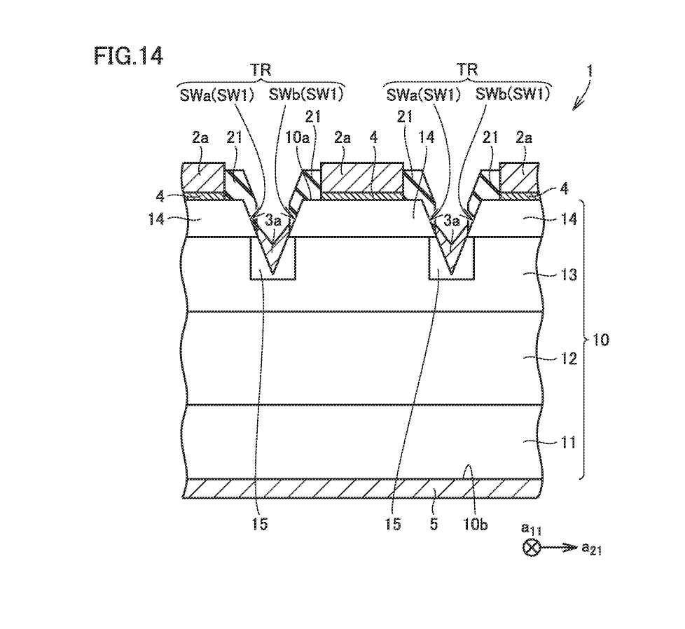

FIG. 14 is a cross-sectional view showing another construction of silicon carbide semiconductor device 1 according to the first embodiment. Referring to FIG. 14, trench TR is not provided with bottom surface BT. Trench TR thus has a cross-sectional shape in what is called a V shape. Namely, sidewall surfaces SWa and SWb continue to each other in p-type layer 13.

According to this construction, an interval between transistor cells along direction a₂₁ can be smaller. Therefore, a density of transistor cells can be higher than in the construction shown in FIG. 2.

### Second Embodiment

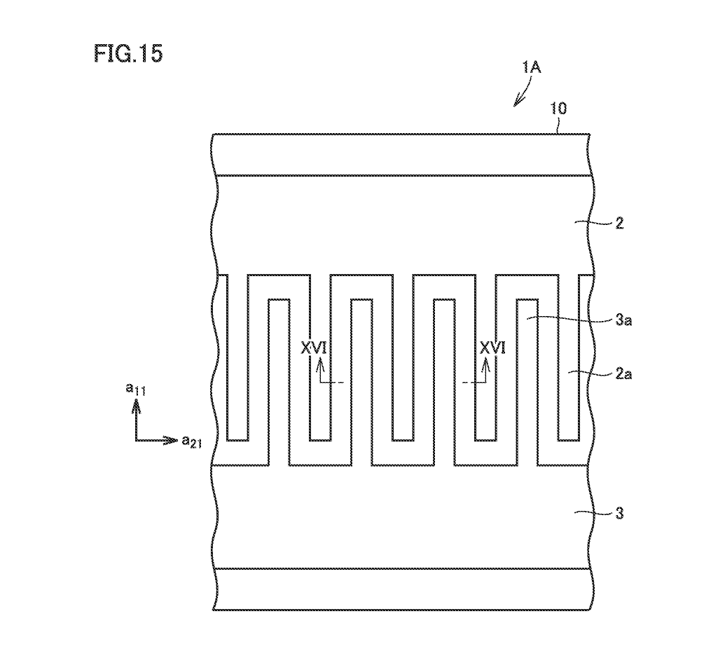

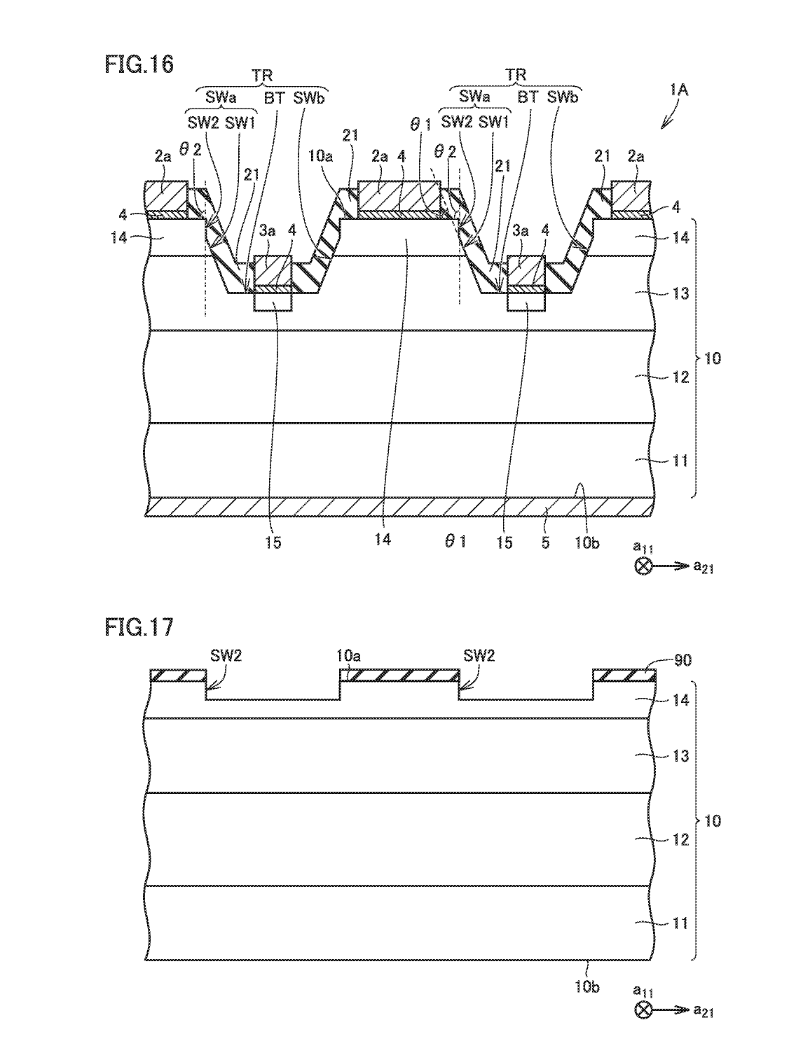

FIG. 15 is a plan view showing a schematic construction of a silicon carbide semiconductor device according to a second embodiment of the present invention. FIG. 16 is a cross-sectional view along the line XVI-XVI in FIG. 15.

Referring to FIGS. 15 and 16, a silicon carbide semiconductor device 1A according to the second embodiment is different from silicon carbide semiconductor device 1 according to the first embodiment in a cross-sectional shape of trench TR.

Each of sidewall surfaces SWa and SWb includes first region SW1 and a second region SW2. First region SW1 is a region including a special surface. Second region SW2 is a region having a depth from first main surface 10a of silicon carbide layer 10 to a position shallower than a junction surface between n⁺ type layer 14 (emitter region) and p-type layer 13 (base region). Furthermore, second region SW2 continues to first region SW1.

An angle θ1 is an angle formed by first region SW1 with respect to first main surface 10a. An angle θ2 is an angle formed by second region SW2 with respect to first main surface 10a. For example, angle θ2 is approximately 90°. Angle θ2 is greater than angle θ1.

A method of manufacturing a silicon carbide semiconductor device according to the second embodiment will now be described. The method of manufacturing a silicon carbide semiconductor device according to the second embodiment is different from the method of manufacturing a silicon carbide semiconductor device according to the first embodiment in the step of forming trench TR. Therefore, the steps of forming trench TR in silicon carbide layer 10 (a fourth step), forming p⁺ type region 15 in p-type layer 13 (a fifth step), and covering a surface of trench TR with an insulating film (a sixth step) will be described below in detail, and detailed description of the steps (first to third and seventh and eighth steps) the same as those in the method of manufacturing silicon carbide semiconductor device 1 according to the first embodiment will not be repeated hereafter.

FIG. 17 is a partial cross-sectional view schematically showing a first treatment performed in the fourth step (the step of forming a trench) in the method of manufacturing silicon carbide semiconductor device 1A according to the second embodiment. Referring to FIG. 17, mask layer 90 having an opening portion is formed on first main surface 10a. In the opening portion in mask layer 90, a portion around a surface of the n⁺ type layer is etched away. For example, reactive ion etching (RIE), in particular, inductively coupled plasma (ICP) RIE, can be employed as an etching method. Specifically, for example, ICP-RIE using SF₆ or a gas mixture of SF₆ and θ2 as a reaction gas can be employed. Through such etching, second region SW2 which is a sidewall surface substantially perpendicular to first main surface 10a is formed in a region where trench TR is to be formed. In this treatment, n⁺ type layer 14 (emitter region) is etched from first main surface 10a of silicon carbide layer 10 to a position shallower than a junction surface between n⁺ type layer 14 and p-type layer 13 (base region).

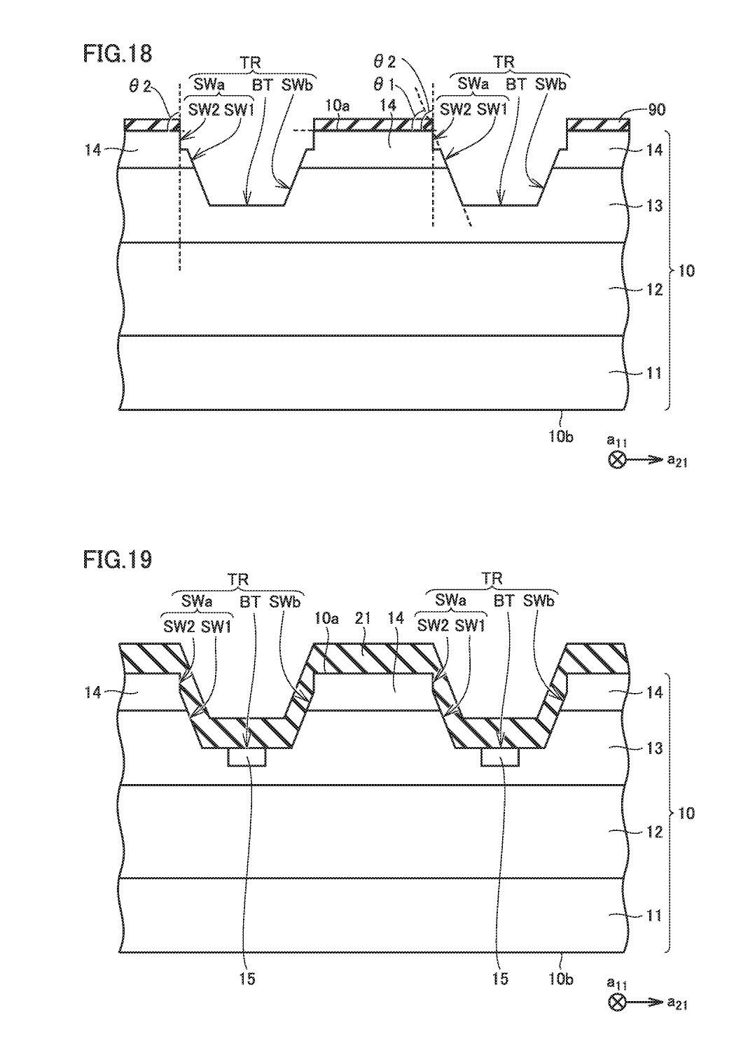

FIG. 18 is a cross-sectional view schematically showing a second treatment performed in the fourth step (the step of forming a trench) in the method of manufacturing silicon carbide semiconductor device 1A according to the second embodiment. Referring to FIG. 18, thermal etching is performed as in the first embodiment. First region SW1 continuing to second region SW2 is thus formed. As described above, angle θ2 is greater than angle θ1.

FIG. 19 is a cross-sectional view schematically showing the fifth and sixth steps in the method of manufacturing silicon carbide semiconductor device 1A according to the second embodiment. Referring to FIG. 19, p⁺ type region 15 is formed in p-type layer 13 in the fifth step. Then, insulating film 21 covering first main surface 10a, sidewall surfaces SWa and SWb, and bottom surface BT is formed in the sixth step.

According to the second embodiment, a current gain of a silicon carbide semiconductor device can be enhanced as in the first embodiment. In particular, according to the second embodiment, prior to formation (thermal etching) of a special surface, a region corresponding to trench TR in first main surface 10a is etched in advance through reactive ion etching. Thus, in subsequent thermal etching, etching of a silicon carbide layer can smoothly proceed. Therefore, a special surface can more reliably be exposed. By forming a trench at which a special surface is exposed, a probability of recombination between holes and electrons in the base region can be lowered. Therefore, a current gain of a silicon carbide semiconductor device can be enhanced.

### Third Embodiment

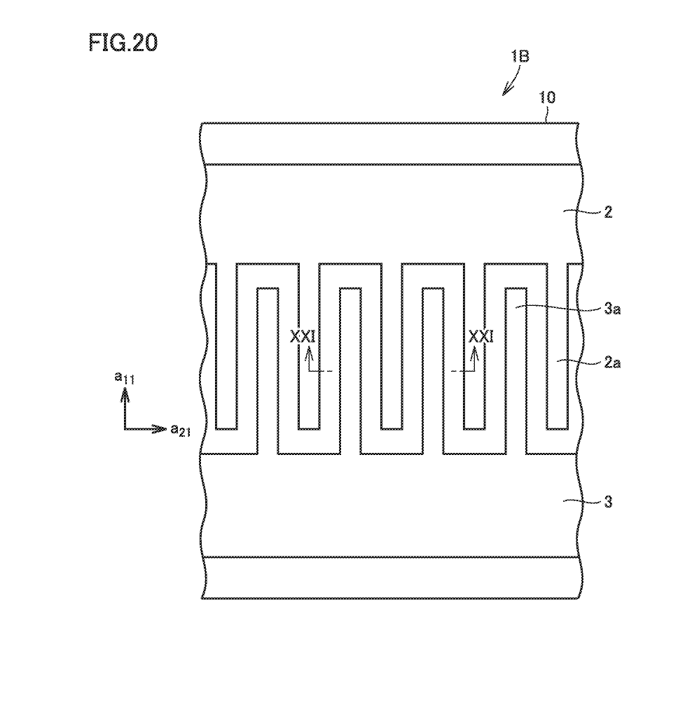

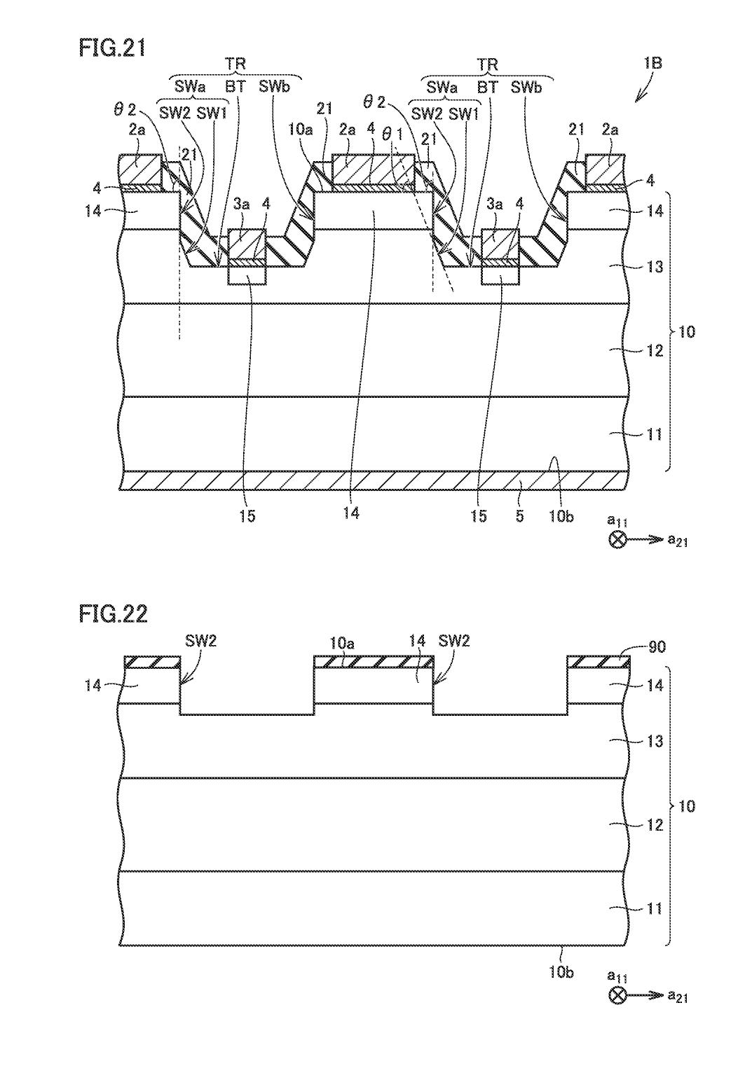

FIG. 20 is a plan view showing a schematic construction of a silicon carbide semiconductor device according to a third embodiment of the present invention. FIG. 21 is a cross-sectional view along the line XXI-XXI in FIG. 20.

Referring to FIGS. 20 and 21, a silicon carbide semiconductor device 1B according to the third embodiment is different from silicon carbide semiconductor device 1 according to the first embodiment and silicon carbide semiconductor device 1A according to the second embodiment in cross-sectional shape of trench TR.

More specifically, each of sidewall surfaces SWa and SWb includes first region SW1 and second region SW2. First region SW1 is a region including a special surface. Second region SW2 is a region continuing from first main surface 10a of silicon carbide layer 10 through n⁺ type layer 14 (emitter region) to first region SW1.

As in the second embodiment, angle θ1 is an angle formed by first region SW1 with respect to first main surface 10a. Angle θ2 is an angle formed by second region SW2 with respect to first main surface 10a. For example, angle θ2 is approximately 90°. Angle θ2 is greater than angle θ1.

A method of manufacturing a silicon carbide semiconductor device according to the third embodiment will be described. As in the description of the second embodiment, the steps of forming trench TR in silicon carbide layer 10 (a fourth step), forming p⁺ type region 15 in p-type layer 13 (a fifth step), and covering a surface of trench TR with an insulating film (a sixth step) will be described in detail, and detailed description of the steps (first to third and seventh and eighth steps) the same as those in the method of manufacturing silicon carbide semiconductor device 1 according to the first embodiment will not be repeated hereafter.

FIG. 22 is a partial cross-sectional view schematically showing a first treatment performed in the fourth step (the step of forming a trench) in the method of manufacturing silicon carbide semiconductor device 1B according to the third embodiment. Referring to FIG. 22, mask layer 90 having an opening portion is formed on first main surface 10a. In the opening portion in mask layer 90, a portion around a surface of n⁺ type layer 14 is etched away through reactive ion etching (RIE), in particular, inductively coupled plasma (ICP) RIE. Through this treatment, second region SW2 is formed to reach p-type layer 13 (base region) from first main surface 10a of silicon carbide layer 10 through n⁺ type layer 14 (emitter region).

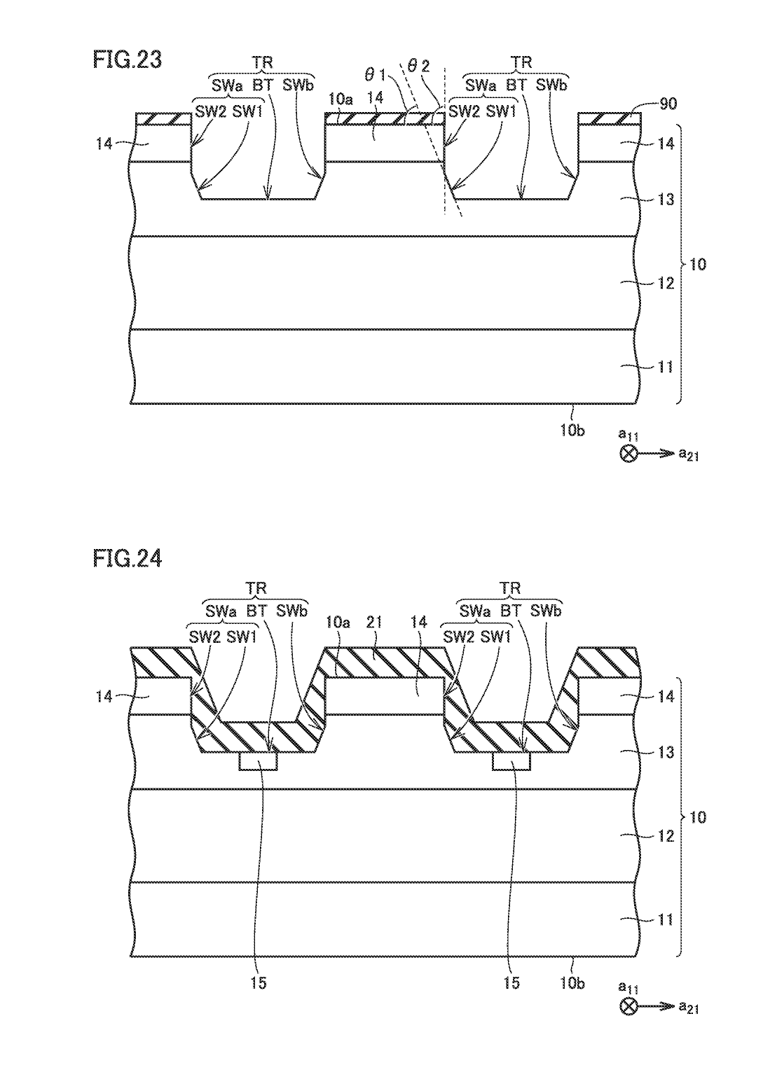

FIG. 23 is a cross-sectional view schematically showing a second treatment performed in the fourth step (the step of forming a trench) in the method of manufacturing silicon carbide semiconductor device 1B according to the third embodiment. Referring to FIG. 23, thermal etching is carried out as in the first and second embodiments. First region SW1 continuing to second region SW2 is thus formed. Angle θ2 is greater than angle θ1.

FIG. 24 is a cross-sectional view schematically showing the fifth and six steps in the method of manufacturing silicon carbide semiconductor device 1B according to the third embodiment. Referring to FIG. 24, p⁺ type region 15 is formed in p-type layer 13 in the fifth step. Then, insulating film 21 covering first main surface 10a, sidewall surfaces SWa and SWb, and bottom surface BT is formed in the sixth step.

According to the third embodiment, a current gain of a silicon carbide semiconductor device can be enhanced as in the first embodiment. According to the third embodiment, as in the second embodiment, prior to formation (thermal etching) of a special surface, a region corresponding to trench TR in first main surface 10a is etched in advance through reactive ion etching. Thus, in subsequent thermal etching, etching of a silicon carbide layer can smoothly proceed.

Furthermore, according to the third embodiment, a junction surface of a pn junction intersects with second region SW2. Second region SW2 is perpendicular to first main surface 10a of silicon carbide layer 10. Therefore, the junction surface of the pn junction and an interface of the pn junction (second region SW2) intersect perpendicularly with each other. A breakdown voltage of the silicon carbide semiconductor device can thus be ensured. In other words, lowering in breakdown voltage of the silicon carbide semiconductor device can be avoided.

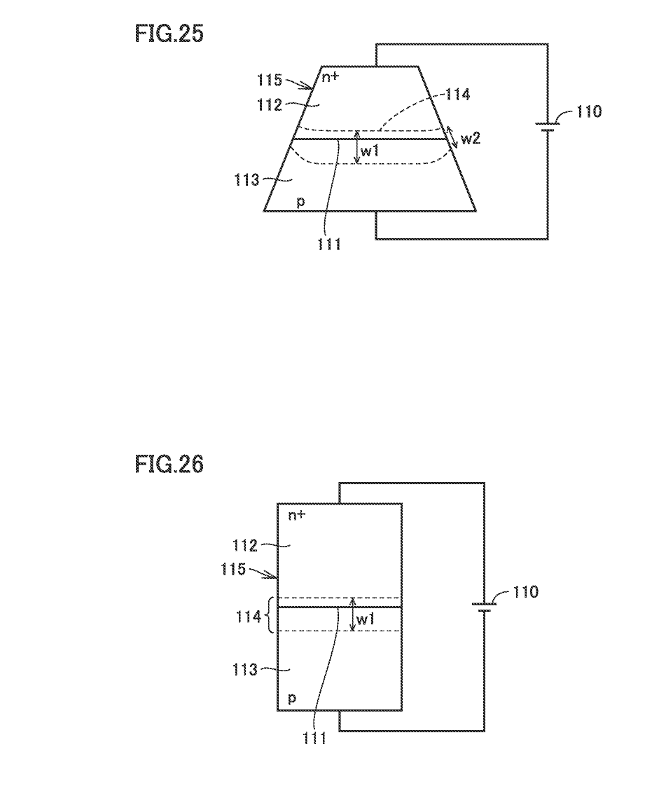

FIG. 25 is a diagram showing a depletion layer extending from a junction surface of a pn junction. Referring to FIG. 25, a power supply 110 applies a reverse bias voltage across an n⁺ type layer 112 and a p-type layer 113. A depletion layer 114 extends from a junction surface 111 between n⁺ type layer 112 and p-type layer 113 to both sides of n⁺ type layer 112 and p-type layer 113. N⁺ type layer 112 corresponds to the emitter region and p-type layer 113 corresponds to the base region. A concentration of an impurity in p-type layer 113 (base region) is relatively low, whereas a concentration of an impurity in n⁺ type layer 112 (emitter region) is relatively high. Therefore, depletion layer 114 extends more toward p-type layer 113 than toward n⁺ type layer 112.

A surface 115 of a semiconductor device constituted of n⁺ type layer 112 and p-type layer 113 is inclined with respect to junction surface 111. A volume of n⁺ type layer 112 is small at an end portion of junction surface 111. Therefore, depletion layer 114 on a side of p-type layer 113 at the end portion of junction surface 111 is smaller in width than in a central portion of junction surface 111. On the other hand, a width of depletion layer 114 on a side of n⁺ type layer 112 is slightly greater at the end portion of junction surface 111 than in the central portion of junction surface 111. A condition of w1>w2, however, is satisfied, where wl represents a width of depletion layer 114 in the central portion of junction surface 111 and w2 represents a width of depletion layer 114 at the end portion of junction surface 111. Since the depletion layer has a width smaller at the end portion of junction surface 111 than in the central portion of junction surface 111, intensity of electric field tends to be high at the end portion of junction surface 111. As a portion where intensity of electric field is higher than in other portions is produced, a breakdown voltage of a semiconductor device tends to lower.

FIG. 26 is another diagram showing a depletion layer extending from a junction surface of a pn junction. Referring to FIG. 26, power supply 110 applies a reverse bias voltage across n⁺ type layer 112 and p-type layer 113. Surface 115 of a semiconductor device constituted of n⁺ type layer 112 and p-type layer 113 is perpendicular to junction surface 111. Therefore, depletion layer 114 evenly extends into both of n⁺ type layer 112 and p-type layer 113. Depletion layer 114 has a width, for example, of w1.

As described above, in the third embodiment, the junction surface between n⁺ type layer 14 (emitter region) and p-type layer 13 (base region) intersects perpendicularly with second region SW2. Therefore, as shown in FIG. 26, the depletion layer extends evenly in both of n⁺ type layer 14 (emitter region) and p-type layer 13 (base region). Therefore, a breakdown voltage of a silicon carbide semiconductor device can be ensured.

In the embodiments above, the n-type is defined as the first conductivity type and the p-type is defined as the second conductivity type different from the first conductivity type. Namely, a silicon carbide semiconductor device according to each embodiment implements an npn bipolar transistor. Thus, ease in manufacturing of a silicon carbide semiconductor device can be improved. The p-type, however, may be defined as the first conductivity type and the n-type may be defined as the second conductivity type. Namely, a silicon carbide semiconductor device according to each embodiment may implement a pnp type bipolar transistor.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

1, 1A, 1B, 101 silicon carbide semiconductor device; 2a emitter electrode; 3a base electrode; 4 ohmic electrode; 5 collector electrode; 10 silicon carbide layer; 10a first main surface; 10b second main surface; 11 n⁺ substrate; 12, 112 n-type layer; 13, 113 p-type layer; 14, 112 n⁺ type layer; 15 p⁺ type region; 16 contact hole; 21 insulating film; 30, 30a region; 90 mask layer; 110 power supply; 111 junction surface; 112, 114 depletion layer; 115 surface; BT bottom surface; IB base current; Ic collector current; IE emitter current; SW1 first region; SW2 second region; SWa, SWb sidewall surface; TR, TR1 trench; a₁, a₁₁, a₂₁, c direction; w1, w2 width (depletion layer); z normal vector; θ off angle; and θ1, θ2 angle.

1. A silicon carbide semiconductor device, comprising:
a silicon carbide layer having hexagonal single-crystal structure,
the silicon carbide layer including
a first main surface,
a second main surface located opposite to the first main surface,
a collector region having a first conductivity type and defining the second main surface,
a base region having a second conductivity type different from the first conductivity type and arranged on a surface of the collector region opposite to the second main surface, and
an emitter region having the first conductivity type, arranged on the base region as being spaced apart from the collector region, and defining the first main surface,
the silicon carbide layer being provided with a trench having a sidewall surface reaching the base region from the first main surface through the emitter region, and
the sidewall surface including a first region macroscopically having an angle not smaller than 50° and not greater than 70° with respect to a {000-1} plane.

2. The silicon carbide semiconductor device according to claim 1, wherein the first region includes a plane having a plane orientation {0-33-8}.

3. The silicon carbide semiconductor device according to claim 1, wherein
the sidewall surface includes two surfaces opposed to each other and coming closer to each other from the first main surface of the silicon carbide layer toward the second main surface.

4. The silicon carbide semiconductor device according to claim 1, wherein
the first region is arranged to lie across the emitter region and the base region,
the sidewall surface further includes a second region having a depth from the first main surface of the silicon carbide layer to a position shallower than a junction surface between the emitter region and the base region and continuing to the first region, and
an angle formed by the second region with respect to the first main surface is greater than an angle formed by the first region with respect to the first main surface.

5. The silicon carbide semiconductor device according to claim 1, wherein
the first region is arranged in the base region,
the sidewall surface further includes a second region continuing from the first main surface of the silicon carbide layer through the emitter region to the first region, and
an angle formed by the second region with respect to the first main surface is greater than an angle formed by the first region with respect to the first main surface.

6. The silicon carbide semiconductor device according to claim 1, wherein
an n-type is defined as the first conductivity type and a p-type is defined as the second conductivity type.

7. A method of manufacturing a silicon carbide semiconductor device, comprising the steps of:
providing a silicon carbide layer having hexagonal single-crystal structure and having a first main surface and a second main surface located opposite to the first main surface,
the step of preparing a silicon carbide layer including the steps of
forming a collector region having a first conductivity type and defining the second main surface,
forming a base region having a second conductivity type different from the first conductivity type on a surface of the collector region opposite to the second main surface, and
forming on the base region, an emitter region having the first conductivity type and defining the first main surface; and
forming a trench having a sidewall surface reaching the base region through the emitter region,
the step of forming a trench including the step of chemically treating the first main surface of the silicon carbide layer for forming a first region macroscopically having an angle not smaller than 50° and not greater than 70° with respect to a {000-1} plane.

8. The method of manufacturing a silicon carbide semiconductor device according to claim 7, wherein
the first region includes a plane having a plane orientation {0-33-8}.

9. The method of manufacturing a silicon carbide semiconductor device according to claim 7, wherein
the step of chemically treating the first main surface includes the step of chemically etching the first main surface of the silicon carbide layer.

10. The method of manufacturing a silicon carbide semiconductor device according to claim 9, wherein
the step of chemically etching the first main surface includes the step of thermally etching the first main surface.

11. The method of manufacturing a silicon carbide semiconductor device according to claim 10, wherein
the step of thermally etching the first main surface includes the step of heating the silicon carbide layer in an atmosphere containing one or more types of halogen atoms.

12. The method of manufacturing a silicon carbide semiconductor device according to claim 11, wherein
the one or more types of halogen atoms include at least any of chlorine atoms and fluorine atoms.

13. The method of manufacturing a silicon carbide semiconductor device according to claim 7, wherein
the step of forming a trench includes the step of etching the first main surface through reactive ion etching prior to the step of chemically treating the first main surface of the silicon carbide layer.

14. The method of manufacturing a silicon carbide semiconductor device according to claim 13, wherein
in the step of etching the first main surface through reactive ion etching, a second region of the sidewall surface is formed by etching the emitter region from the first main surface of the silicon carbide layer to a position shallower than a junction surface between the emitter region and the base region.

15. The method of manufacturing a silicon carbide semiconductor device according to claim 13, wherein
in the step of etching the first main surface through reactive ion etching, a second region of the sidewall surface reaching the base region from the first main surface of the silicon carbide layer through the emitter region is formed.

16. The method of manufacturing a silicon carbide semiconductor device according to claim 7, wherein
the step of forming a base region includes the step of forming a layer having the second conductivity type on the collector region through epitaxial growth.

17. The method of manufacturing a silicon carbide semiconductor device according to claim 7, wherein
the step of forming an emitter region includes the step of forming a layer having the first conductivity type on the base region through epitaxial growth.

18. The method of manufacturing a silicon carbide semiconductor device according to claim 7, wherein
an n-type is defined as the first conductivity type and a p-type is defined as the second conductivity type.
